(19) United States
(12) Patent Application Publication
(10) Pub. No.: US 2024/0427970 A1
(43) Pub. Date: Dec. 26, 2024

(54) CONTROLLING PROCESS SIMULATION MODELS WITH DIGITAL AGENTS

(71) Applicant: Saudi Arabian Oil Company, Dhahran (SA)

(72) Inventors: Ahmed A. Shaikh, Dhahran (SA); Yuk San Man, Dhahran (SA); Ahmed Suleiman Ibrahiem Al Meqdadi, Dhahran (SA)

(21) Appl. No.: 18/749,052

(22) Filed: Jun. 20, 2024

Related U.S. Application Data
(60) Provisional application No. 63/509,460, filed on Jun. 21, 2023.

(51) Int. Cl. G06F 30/27

(52) U.S. Cl. CPC G06F 30/27

(57) ABSTRACT

Methods and systems are configured for executing a production simulation by receiving, through a client device, an instruction for executing a portion of a production simulation; responsive to receiving the instruction, accessing one or more digital agents, the one or more digital agents configured and trained with training data representing actions for operating one or more production simulations, the training data associating one or more simulation assets with respective data signatures each representing a scenario for executing a given simulation asset within the production simulation, wherein at least one of the one or more simulation assets includes the portion of the production simulation; accessing, by the one or more digital agents, the simulation asset including the portion of the production simulation of the instruction; executing the portion of the production simulation to generate output data; and providing the output data to the client device.

### CLAIM OF PRIORITY

This application claims priority under 35 U.S.C. § 119 (e) to U.S. Patent Application Ser. No. 63/509,460, filed on Jun. 21, 2023, the entire contents of which are hereby incorporated by reference.

### TECHNICAL FIELD

This specification relates generally to production simulations associated with gas field and oilfield production. For example, this specification describes digital agent interfaces for use in reservoir simulations and reservoir process control systems.

### BACKGROUND

A data processing system can simulate operations of the reservoir using production simulators. The production simulators are configured to simulate the operation of geophysics within the reservoir in response to various operations in the reservoir, such as performing hydraulic fracturing, performing well drilling, performing seismic measurements, or other operations in the reservoir. In some implementations, hardware within the reservoir can be emulated using a digital twin. A digital twin is a digital representation of an intended or actual real-world physical product, system, or process (a physical twin) that serves as the effectively indistinguishable digital counterpart of it for practical purposes, such as simulation, integration, testing, monitoring, and maintenance.

### SUMMARY

This disclosure describes digital agents which operate as an interface between a production simulator and an operator of the production simulator. The one or more digital agents may enable a user to operate the production simulator correctly by providing guided instructions for operating the production simulation while a simulation is taking place. For example, the digital agent may suggest which aspects of the simulation should be changed, which simulator assets should be leveraged, how the simulator should be controlled during execution, flag any potential errors or inconsistencies for simulation operation, and otherwise guide execution of the production simulator.

A data processing system includes one or more digital agents that are configured to detect when a specific asset for a production simulator is potentially useful and suggest the one or more simulator assets to the user. The one or more digital agents are trained to detect, and offer, which simulation scenarios generally require the use of specific assets of the production simulator in order to successfully simulate them. The one or more digital agents therefore can greatly assist a technician in operation of the production simulator and guide the technician to properly simulate the asset and in a manner that is consistent with other simulations that are being performed. The one or more digital agents are software platforms independent and issue commands accordingly to execute the chosen simulation accordingly.

The described implementations can provide numerous technical benefits. Production simulators execute on specialized client devices that include specialized interfaces. The interfaces for production simulators are based on the operations of this production simulator, which include many (e.g., dozens of) inputs, controls, and other interactive objects for controlling the simulation of the production. The interface is complicated and therefore requires substantial training for the production simulations to be executed to obtain a reasonable simulation output.

In addition to the specialized interface, there is minimal automation between the interface of the production simulators and the corresponding digital twins or other simulation assets that are available to the production simulator. For example, the production simulator may have submodules, digital twin assets, or other sub-simulations to execute within the larger production simulation. These simulator assets may need to be activated by an operator at specific times or in specific circumstances that are recognized by a trained user. The execution of the production simulation can therefore an experienced technician to manually operate the production simulator such as leveraging one or more of the available assets at specific times or in specific circumstances. In this example an experienced technician may be a technician with understanding of the production or other desired outcomes of the production simulation. The technician has an intimate understanding of the available assets. The technician understands when to access and execute these assets during the production simulation to enable and optimal simulator output. The production simulation may therefore be inconsistent depending on the skill of the given operator of the simulator.

To overcome these issues, a digital agent acts as an interface between the production simulator and the operator. The digital agent guides a user for operation of the production simulator during the simulation. The digital agent includes an intuitive interface that enables an untrained user to operate the production simulator without pre-existing knowledge of the interface and which specific controls and digital assets are in the production simulator. Additionally, the digital agent enables a user that does not have pre-existing understanding of process concepts to successfully operate the production simulator. The digital agent can guide operation of the simulation by suggesting various simulator assets to execute at appropriate times and specifying what various outcomes can be achieved by executing these simulator assets.

One or more of the above advantages are enabled by the following embodiments.

In a general aspect, a method for executing a production simulation includes receiving, through a client device, an instruction for executing a portion of a production simulation; responsive to receiving the instruction, accessing one or more digital agents, the one or more digital agents configured and trained with training data representing actions for operating one or more production simulations, the training data associating one or more simulation assets with respective data signatures each representing a scenario for executing a given simulation asset within the production simulation, wherein at least one of the one or more simulation assets includes the portion of the production simulation; accessing, by the one or more digital agents, the simulation asset including the portion of the production simulation of the instruction; executing the portion of the production simulation to generate output data; and providing the output data to the client device.

In some implementations the one or more digital agents are available to the client device as a service.

In some implementations, the one or more simulation assets include a digital twin representing a piece of physical hardware in the production.

In some implementations, the one or more simulation assets include a sub-simulation asset, the sub-simulation asset configured to generate a specific data output that is specified in the instruction.

In some implementations, the instruction is received through an interface comprising a chat bot or a digital input interface.

In some implementations, the instruction is received responsive to providing the client device with one or more options for executing their production simulation.

In some implementations the process includes providing, to the client device, one or more suggestions for one or more prerequisite portions of the production simulation that is required prior to executing the portion of the production simulation identified in the instruction.

In some implementations a system is configured for executing a production simulation. The includes one or more processors; and a memory storing instructions that, when executed by the one or more processors, cause the one or more processors to perform the operations of the previously described processes.

In a general aspect, one or more non-transitory computer readable media store instructions for executing a production simulation. The instructions, when executed by one or more processors, are configured for causing the one or more processors to perform the previously described processes.

The details of one or more embodiments are set forth in the accompanying drawings and the description below. Other features and advantages will be apparent from the description and drawings, and from the claims.

### BRIEF DESCRIPTION OF THE DRAWINGS

FIG. 1A illustrates an interface for one or more digital agents.

FIG. 1B illustrates an interface for one or more physical platforms.

FIG. 1C illustrates an example system for hydrocarbon well production.

FIG. 2 illustrates a flow diagram showing a process for using one or more digital agents to execute a production simulation.

FIG. 3 illustrates a flow diagram showing a process for using one or more digital agents to execute a production simulation.

FIG. 4 is a diagram of an example computing system.

FIG. 5 is a diagram of example hydrocarbon production operations.

### DETAILED DESCRIPTION

This disclosure describes a data processing system including one or more digital agents that together provide an automated interface between one or more assets of a production simulator and an operator of the production simulator. The one or more digital agents may enable a user to operate the production simulator by providing guided instructions for operating the production simulator while a simulation is taking place. For example, the digital agent may suggest updates to one or more parameter values of the simulator, which simulator assets or models should be leveraged in a given scenario, flag any potential errors or inconsistencies in operation, and otherwise guide a user during performance of the production simulator.

In some implementations, the one or more digital agents are configured to automatically launch, execute, and terminate assets model from a library of available asset models. The one or more digital agents are further configured to obtain simulation results by automatically updating operating parameter values without user intervention or with minimal user validation of such a change. The one or more digital agents therefore not only guide users to properly execute the production simulator but can also minimize or eliminate errors or other faults that may be introduced by the operator. The one or more digital agents also as previously stated can leverage the full library of available models depending on the particular scenario of the production simulation. The one or more digital agents can be trained based on prior previously run simulations to detect when each available model or other simulation asset is appropriate to suggest for execution or to execute automatically.

The one or more digital agents can provide an interface between the production simulation layer and the computing network of an entire organization that is operating many production simulations. Therefore, a specific production simulation can be available through the interface provided by the one or more digital agents to any user that is able to access the network. For example, the data processing system provides the one or more digital agents as a service to users on the network such that any user may access one or more digital agents for any production simulation. The data processing system makes the one or more digital agents available using remote call functions or any other supported methods as interfaces with simulation models/digital twins.

A user, through the interface of the one or more digital agents, can interact using written text or human speech with the agents to make requests and obtain results. These requests will trigger the agent to execute a specific model which is already developed and resides in an internal cloud or local workstation. The digital agent asks the user to wait until the model run is complete and then extract the results and present them to the user in a less technical form. If required, the user may be able to interact further with the agent to further interrogate into the results or asks for further information.

As described previously, the one or more digital agents can control or represent digital twins corresponding to physical hardware of a production facility. The physical hardware can include hardware for extracting hydrocarbons from a reservoir, refining hydrocarbons produced from a reservoir, or subsets of hardware for either of these scenarios or both of these scenarios. In these cases, the simulation is tailored to function exactly as the physical hardware it represents. A user can generate one or more control commands for operating the physical hardware that are first simulated using the digital twins of the interface. For example, the inputs and outputs of each simulation can mirror those provided to the physical hardware represented by the one or more digital twins controllable through the user interface.

In some implementations, the interface that is used for controlling the one or more digital twins can be used to control physical hardware represented by the one or more digital twins, such as when a simulation is successful. For example, the natural language input enabled by the chat bot or other interface can be used for controlling physical hardware for hydrocarbon production, the chat bot can be enabled for controlling physical hardware when simulations using the natural language inputs are successful or otherwise validated as properly performing the hydrocarbon production operations of the simulation. For example, when a natural language model for a particular digital asset is trained And simulations using that trained model are successful, the trained model can be applied to process natural language inputs for controlling physical hardware.

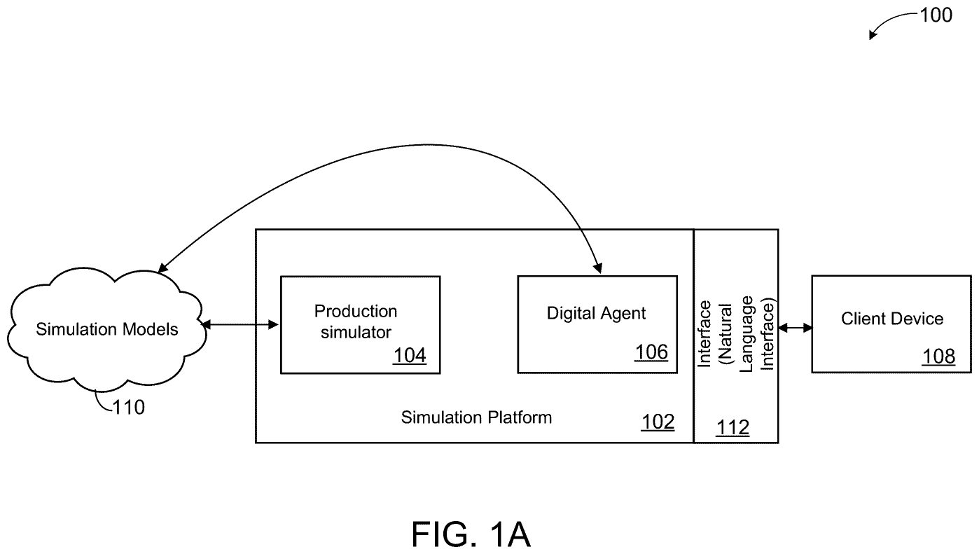

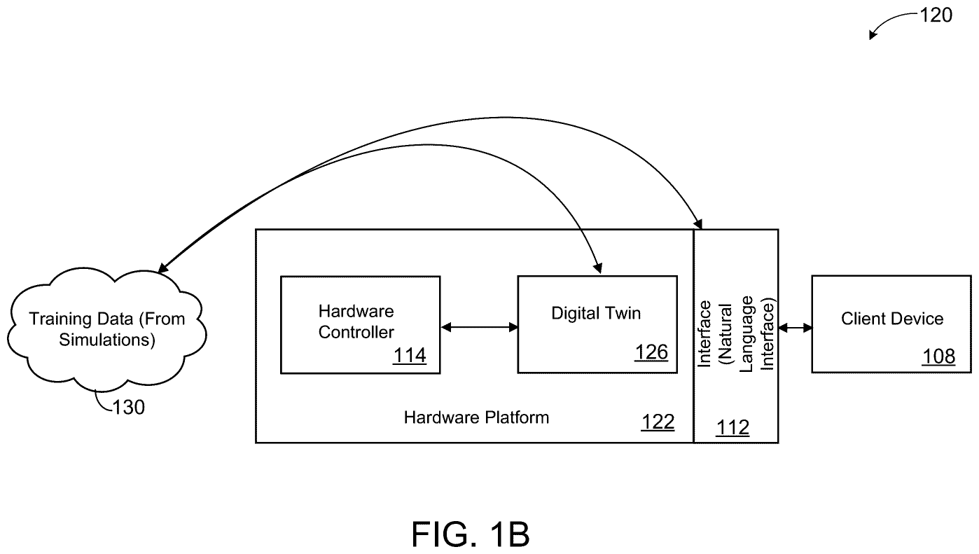

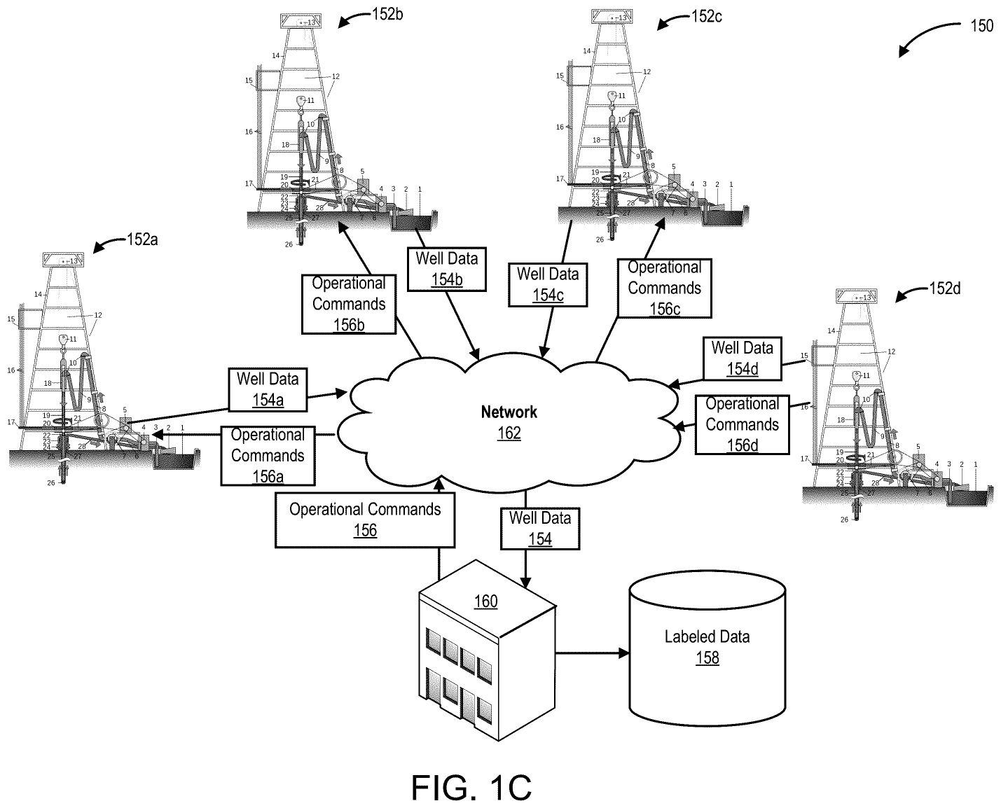

FIG. 1A illustrates a system 100 including an interface 112 for one or more digital agents 106 and a production simulator 104. The digital agents 106 and production simulator 104 together form a simulation platform 102. The one or more digital agents 106 can access one or more simulation models 110. The one or more digital agents 106 can use the simulation models 110 part of the production simulation. For example, the one or more digital agents 106 access the simulation models and suggest which of these assets are to be used as part of the production simulator 104.

The one or more digital agents can include logic that specifies which circumstances of the simulation correspond to which simulation models 110. The one or more digital agents 106 are configured to recommend or suggest specific models, digital twins, or other simulation assets that are relevant to a particular production simulation. The one or more digital agents 106 may suggest specific parameter change to be inputted into the production model. For example, if a throughput capacity simulation is being executed, the digital agent 106 may recommend a specific set of flowrates to be inserted into the production simulation. In another example, if a rating simulation on a specific equipment is being performed, the digital agent may recommend specific parameters for adjustments and their values to be set as part of the simulation. In these examples, the digital agents 106 are configured to recommend specific parameters, models, digital twin assets, control adjustments, or other aspects of the simulation in order to guide a user to operate the simulator properly.

The one or more digital agents 106 may also constrain the production simulation in order to achieve realistic outcomes or otherwise guide a user in selection of parameter values. For example, if incompatible equipment is linked inside the simulation, the digital agents 106 may highlight this fault to the user and recommend an alternative equipment configuration. Such recommendations enable a user without specialized training or experience to configure and execute a production simulation fully utilizing all of the available simulation models 110 and other simulator assets that are available without having extensive knowledge of these available assets.

The one or more digital agents 106 may detect specific circumstances under which one or more simulation models 110 are appropriate for recommending to the user. For example, when data values of the simulation represent a specific data signature, the digital agent 106 may detect that a particular simulation model may need to be executed. The specific thresholds of these data values or parameter values maybe set based on training the digital agents 106 using machine learning approaches. For example, prior simulations that have been executed can be used as training data to train the one or more digital agents 106 in determining when specific assets of the simulation models 110 have been accessed during a production simulation and under what circumstances those simulation models were used. These training data can train the one or more digital agents 106 and therefore leverage prior production simulations that were executed by experienced technicians in order to recommend options for future production simulations executed by untrained users.

The data processing system 100 includes an interface 112. The interface 112 can include a user interface that simplifies operation of the simulation platform 102. The interface 112 can include more than just a visual user interface. The interface 112 can include dynamic controls that are generated based on the underlying intelligence of the one or more digital agents 106. For example, the interface 112 can be configured to ingest local commands of a user. In some implementations, the interface 112 is configured to automatically display or suggest various simulation model assets 110 to a user of a client device 108. The interface 112 may include a visualization of the execution of the production simulation. Generally, the purpose of the interface 112 is to greatly simplify the user interface of the production simulator 104 by removing access controls and instead allowing the one or more digital agents to suggest changes or updates to the production simulation as required during execution of the simulation. The interface 112 can therefore include only a few visual controls and can be generally operated based on responding to suggestions, alerts, recommendations, or other dynamically generated controls that only are displayed at a time in which those controls are relevant to changing operation of the production simulation.

The user commands can include natural language queries that are interpreted by language models of the simulation. The language models can be tailored to correspond to the specific circumstances under which the simulation is being executed. For example, depending on the physical hardware being simulated by the one or more digital twins of the simulation, particular commands can cause particular control signals to be generated for controlling one or more digital twins that are simulating the physical hardware. A language model can enable a user to execute complex operations without extensive training or specialized knowledge. For example, in particular production operations, user can be prompted to perform a particular test or request a specific sensor reading at a point in time at which the user should be doing so when operating the physical hardware Represented by the one or more digital twins of the simulation.

A language model can be associated with each digital asset such as each respective simulation model or each of the one or more digital twins. For example, a language model can operate using a particular vocabulary for a particular simulation or other digital asset. Different natural language commands can be associated with different control inputs for operating the physical hardware represented by digital twin or otherwise operating the simulation. For a different digital twin or simulation, the same vocabulary may correspond to a different input for controlling the physical hardware represented by the digital twin or for the simulation. Each of the language models can be trained for its particular simulation or other digital asset such as a digital twin to enable a user to input natural language queries that will always correspond to valid inputs for controlling the simulation or physical hardware represented by the digital twin. Therefore, a user can operate a complex hydrocarbon production operation for a particular facility without specialized training for operations at that particular facility, that particular set of hardware or simulation, or other specialized knowledge.

FIG. 1B illustrates a system 120 for controlling one or more physical platforms 122. The client device 108 can be used to input natural language queries into an interface 112. The interface 112 can be trained with a particular language model based on training data 130 received from simulations as described herein. The training data 130 can be input into the digital twin 126 representing the hardware of the hardware platform 122 and can communicate with hardware controllers 114 that operate the hardware of the hardware platform 122.

The system 120 enables a user to interact with the hardware platform 122 using natural language queries using the natural language interface 112. Inputs, or commands provided through the interface 112 are recognized by the digital twin digital asset 126 which provides appropriate control inputs to the hardware controllers 114 for operation of hardware of the hardware platform 122. The digital twin 126 translates the natural language command(s) into inputs for the hardware controller 114 for causing the hardware platform 122 to perform the action of the natural language command. The digital twin 126, or other digital asset, can generate responses to the natural language queries provided though the interface 112. In some implementations, the digital twin 126 can generate prompts for additional commands or instructions for further controlling the hardware platform 122. The prompts or commands can be generated by the interface 112 responsive to receiving data, from the digital twin 126 or other digital asset, that the hardware platform 122 has completed execution of operations represented by one or more previous commands received through the interface 112.

FIG. 1C shows a system 150 for hydrocarbon well production. The system 150 includes a plurality of wells 152a-d (collectively wells 152), a control center 160, and a network 162. The plurality of wells 152 are at various locations in a reservoir and can each include a well drilling rig 152a-d. Generally, each of the wells 152a-d includes one or more sensors that are configured to measure data during the drilling and production processes. The sensors of each well 152a-d are configured to measure respective well data 154a-d (collectively well data 154) such as flow rate in a wellbore, a wellbore pressure, a wellbore temperature, fluid composition, a well depth, and so forth. Each of the wells 152 sends respective well data 154a-d over the network 162 to the control center 160. The control center 160 includes a data processing system that is configured to receive the well data 154, process the well data, and generate operational commands 156a-d (collectively operational commands 156) for each of the respective wells 152a-d. The operational commands 156 are configured to control well production at each of the respective wells 154a-d. The well production is controlled based on an optimal well production that is determined by the data processing system at the control center 160. The optimal well production represents a maximum or nearly maximum well production that a given well can output based on the constraints of the reservoir and of the hardware at the actual well rig.

Each of the one or more wells 152 can be represented by a digital twin (e.g., digital twin 126). Each of the one or more wells can be simulated by one or more digital agents 106. The simulation models 110 and digital twins 126 described previously can be trained based on operational data from the physical hardware of the system 150. The simulation models 110 can be hyper accurate to train the digital twins 126 for high-fidelity emulation of the hardware assets (e.g., of the hardware platform 122). For example, the labeled data 158 can be used for training the simulation models 130 for generating the digital twins 126. The labeled data 158 represents operational data of the hardware that are labeled with specific actions representing an action or operation for that hardware. The action or operation can be triggered through natural language commands through the interface 112. For example, sensor data from the hardware, such as wells 152a-d or from the production facility 160, can be labeled with the operation that is represented by those sensor data. The simulation models 130 can be trained to mimic these sensor readings, from particular hardware, responsive to input commands through the interface 112. The digital twins 126 of these hardware elements are thereby capable of high-fidelity emulation the hardware.

In some implementations, responsive to the measured values of the respective production variables at a well, the data processing system of production facility 160 is configured to determine a target production for that well and one or more other wells at the reservoir. For example, the data processing system is configured to maximize oil production overall in a reservoir by monitoring production from each of the individual wells 152a-d within the reservoir. The data processing system is configured to periodically or continuously receive well data 154 from the wells 152, the process the well data using the optimization model subsequently described and update well production targets to optimize hydrocarbon output at the reservoir. The data processing system is configured to generate operational commands 156 that cause the wells 152 to produce at or near the respective target production rates specified by the output of the optimization model. The operational commands specify instructions that because the hardware at the respective wells 152a-d to pump water, extract hydrocarbons, or otherwise operate the well to achieve the specified target production.

The data processing system of the production facility 160 controls operation of each of the wells 152 at a reservoir to maximize overall hydrocarbon production for the reservoir. For example, the data processing system can set production rates for a particular well 152a-d based on production rates set for one or more of the other wells 152a-d at the reservoir. In an example, the data processing system maximizes a hydrocarbon production for a particular well in the reservoir without accounting for production rates at one or more other wells at the reservoir. In some implementations, the data processing system can be controlled through the interface 112 for inputting commands to control operations of the one or more wells 152a-d.

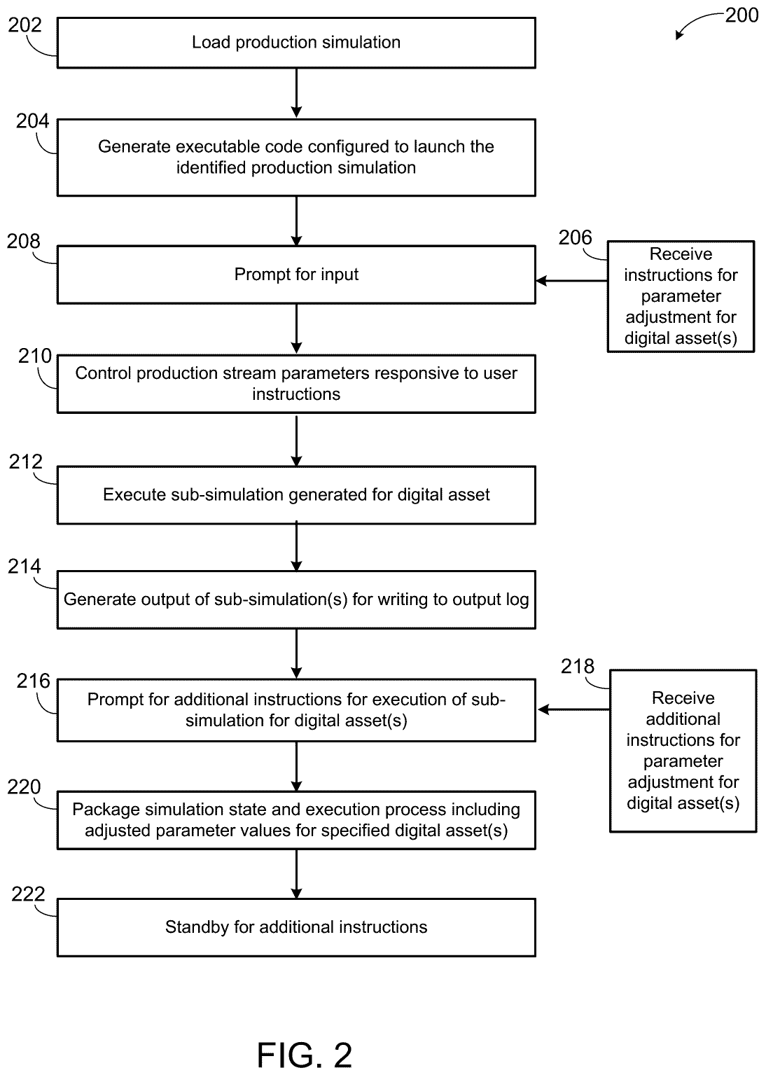

FIG. 2 illustrates a flow diagram showing a process 200 for using one or more digital agents to execute a production simulation. The process 200 can be executed by the data processing system 100 described in reference to FIGS. 1A-1B. the process 200 can include receiving, at step 202, a user command that loads a production simulation. The user command can simply include a title, name, general subject matter, or other reference to the simulation that is to be executed. The one or more digital agents previously described in reference to FIGS. 1A-1B can interpret the command and identify one or more simulations that are intended to be loaded by the user. And some implementations, the one or more digital agents may suggest or list the most relevant production simulations based on the command input by the user.

The data processing system, at step 204 of processed 200, is configured to automatically generate executable code configured to launch the identified production simulation. At step 208, the data processing system is configured to prompt the user when the simulation is ready to be executed. The one or more digital agents prompt the user for options specifying exactly how the production simulation is to be executed. For example, a user command can specify that a simulation stream is intended to be adjusted, or that one or more parameter values are to be changed. For example, the one or more parameter values can include adjustment of a stream temperature, flow rate, pressure, and so forth.

The data processing system, at step 210 of process 200, is configured to send the generated executable code including the instructions to execute the production simulation. For example, as shown in FIG. 2, a user command specifying that a temperature change is to be introduced is received at step 208. The one or more digital agents configure the instruction to comport with the input of the production simulation. At step 210, the one or more digital agents send the instruction to adjust the stream temperature to the production simulator 104. In this example, adjusting the stream temperature is one or more of the available commands or sub-simulations that can be performed from the set of available simulations 110, previously described.

The data processing system, at step 212 of process 200, is configured to execute the sub module or sub-simulation that was specified in the command 210 that was generated by the one or more digital agents. At step 212, the one or more sub-simulations Execute and generate output data. Once the sub-simulations have executed, the one or more digital agents are configured to stream the output data to the client device 108 of the user. As shown in this example, a user can simply speak, write, or otherwise input as simple instruction into the one or more digital agents, and the one or more digital agents can interpret this command, access the appropriate sub-simulation, and cause the desired portion of the production simulator to execute and generate the requested data. This guides the user to execute the requested sub-simulation without enabling the user to upset or otherwise introduce errors to other portions of the production simulation that is executing.

The data processing system, at step 214 of process 200, is configured to automatically write, if necessary, the output data to a particular database that is specified as receiving such data. Therefore, the necessary data is automatically stored at the location that is expected in the production simulation environment.

At step 216 of process 200 the data processing system again prompts the user for further input. At step 216, the production simulation has completed the previously requested sub-simulations and is ready for further portions of the production simulation to be executed. A user of the client device 108 can therefore understand that the production simulation is ready for further input. In the example shown in process 200, at step 218, the user command is received to save the state of the production simulation and exit the simulation.

Further instructions or other sub-simulations can be instructed to execute at this stage. For example, if an invalid sub-simulation or simulation model is requested, the one or more digital agents may specify which other sub-simulations or other aspects of the production simulation are required as prerequisites before the requested sub-simulation can be executed. In this way, the one or more digital agents of the data processing system guide the user to properly execute the production simulation. The one or more digital agents ensure that the user causes one or more specific sub-simulations to be executed in the correct sequence. The one or digital agents ensure that the production simulation generates all prerequisite data before a particular sub-simulation for production asset is executed. The one or more digital agents therefore streamline the execution of the production simulation because they recommend or otherwise guide the user to perform sub-simulations in the proper sequence. In some examples, the one or more digital agents assessed an untrained user by specifying which unexecuted sub-simulations or other models are to be executed prior to the identified model. The one or more digital agents assist a user in obtaining the desired results quickly and efficiently. The guided use of the production simulator ensures that the generated simulation results are valid.

Additionally, the one or more digital agents can represent digital twins, as previously described. This enables a user to perform a realistic simulation of a particular production facility rather than a generic production facility. For example, a user can train using digital twins representing the physical hardware of a particular production facility that the user subsequently operates for extraction of hydrocarbons. The guided simulation can enable a user to familiarize him or herself with the physical hardware of the production facility.

The data processing system, at step 220 of process 200, is configured to generate the command for saving the production simulation at its current state and exiting the production simulation. The data processing system is configured, at step 222, to await further instructions.

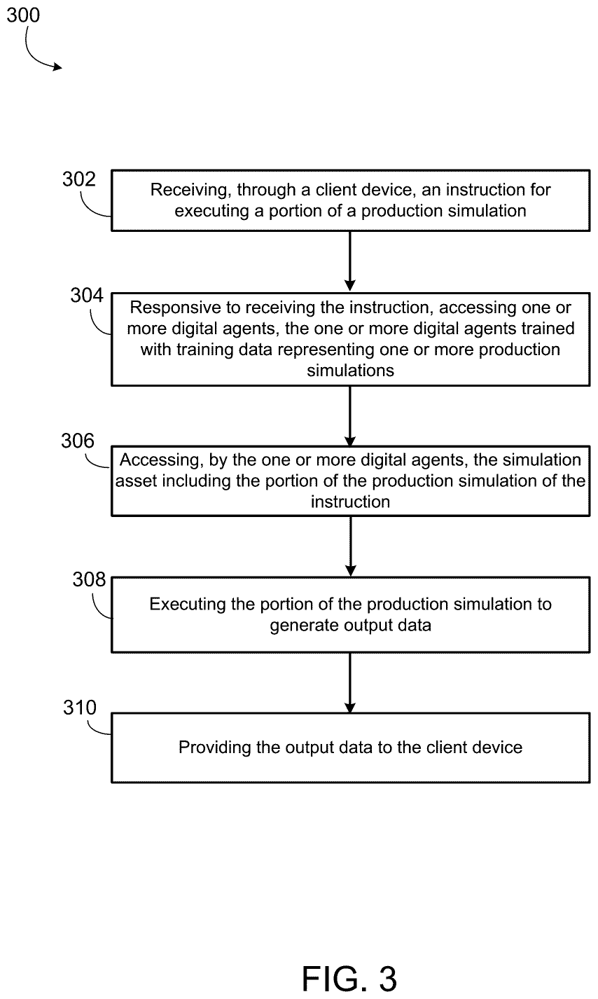

FIG. 3 illustrates a flow diagram showing a process 300 for using one or more digital agents to execute a production simulation. The data processing system 100 previously described can be configured to execute process 300. The process 300 includes receiving (302), through a client device, an instruction for executing a portion of a production simulation. The process 300 includes, responsive to receiving the instruction, accessing (304) one or more digital agents. The one or more digital agents are trained with training data representing one or more production simulations, the training data associating one or more simulation assets with respective data signatures each representing a scenario for executing a given simulation asset within the production simulation. At least one of the one or more simulation assets includes the portion of the production simulation. The process 300 includes accessing (306), by the one or more digital agents, the simulation asset including the portion of the production simulation of the instruction, the process 300 includes executing (308) the portion of the production simulation to generate output data. the process 300 includes providing (310) the output data to the client device.

In some implementations, the one or more digital agents are available to the client device as a service. In some implementations, the one or more simulation assets include a digital twin representing the process or production. In some implementations, the one or more simulation assets include a sub-simulation asset. The sub-simulation asset is configured to generate a specific data output that is specified in the instruction. In some implementations, the instruction is received through an interface comprising a chatbot. In some implementations, the instruction is received responsive to providing the client device with one or more options for executing their production simulation.

In some implementations, the process 300 includes providing, to the client device, one or more suggestions for one or more prerequisite portions of the production simulation that is required prior to executing the portion of the production simulation identified in the instruction.

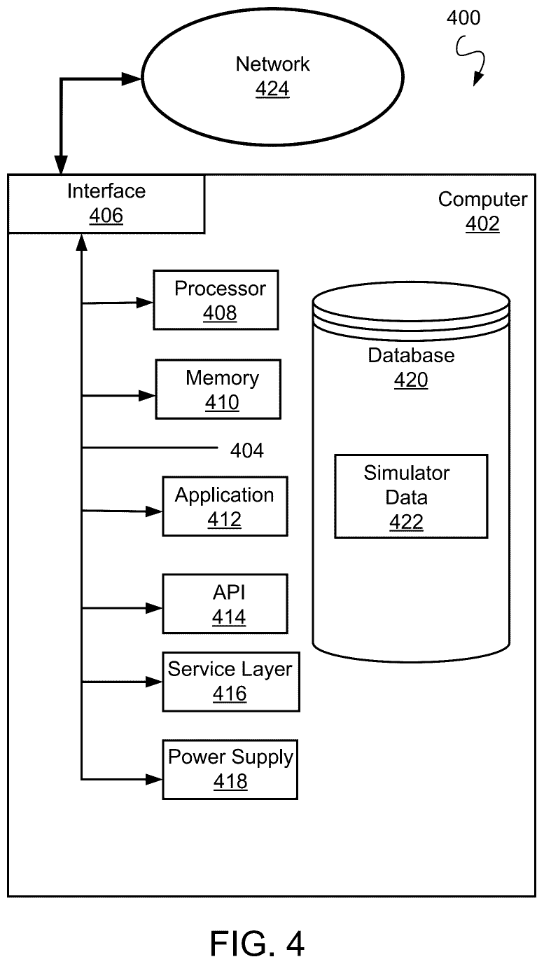

FIG. 4 is a block diagram of an example computing system 400 used to provide computational functionalities associated with described algorithms, methods, functions, processes, flows, and procedures described in the present disclosure, according to some implementations of the present disclosure. The illustrated computer 402 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 402 can include input devices such as keypads, keyboards, and touch screens that can accept user information. Also, the computer 402 can include output devices that can convey information associated with the operation of the computer 402. The information can include digital data, visual data, audio information, or a combination of information. The information can be presented in a graphical user interface (UI) (or GUI).

The computer 402 can serve in a role as a client, a network component, a server, a database, a persistency, or components of a computer system for performing the subject matter described in the present disclosure. The illustrated computer 402 is communicably coupled with a network 424. In some implementations, one or more components of the computer 402 can be configured to operate within different environments, including cloud-computing-based environments, local environments, global environments, and combinations of environments.

The computer 402 is an electronic computing device operable to receive, transmit, process, store, and manage data and information associated with the described subject matter. According to some implementations, the computer 402 can also include, or be communicably coupled with, an application server, an email server, a web server, a caching server, a streaming data server, or a combination of servers.

The computer 402 can receive requests over network 424 from a client application (for example, executing on another computer 402). The computer 402 can respond to the received requests by processing the received requests using software applications. Requests can also be sent to the computer 402 from internal users (for example, from a command console), external (or third) parties, automated applications, entities, individuals, systems, and computers.

Each of the components of the computer 402 can communicate using a system bus 404. In some implementations, any or all the components of the computer 402, including hardware or software components, can interface with each other or the interface 406 (or a combination of both), over the system bus 404. Interfaces can use an application programming interface (API) 414, a service layer 416, or a combination of the API 414 and service layer 416. The API 414 can include specifications for routines, data structures, and object classes. The API 414 can be either computer-language independent or dependent. The API 414 can refer to a complete interface, a single function, or a set of APIs.

The service layer 416 can provide software services to the computer 402 and other components (whether illustrated or not) that are communicably coupled to the computer 402. The functionality of the computer 402 can be accessible for all service consumers using this service layer. Software services, such as those provided by the service layer 416, can provide reusable, defined functionalities through a defined interface. For example, the interface can be software written in JAVA, C++, or a language providing data in extensible markup language (XML) format. While illustrated as an integrated component of the computer 402, in alternative implementations, the API 414 or the service layer 416 can be stand-alone components in relation to other components of the computer 402 and other components communicably coupled to the computer 402. Moreover, any or all parts of the API 414 or the service layer 416 can be implemented as child or sub-modules of another software module, enterprise application, or hardware module without departing from the scope of the present disclosure.

The computer 402 includes an interface 406. Although illustrated as a single interface 406 in FIG. 4, two or more interfaces 406 can be used according to needs, desires, or particular implementations of the computer 402 and the described functionality. The interface 406 can be used by the computer 402 for communicating with other systems that are connected to the network 424 (whether illustrated or not) in a distributed environment. Generally, the interface 406 can include, or be implemented using, logic encoded in software or hardware (or a combination of software and hardware) operable to communicate with the network 424. More specifically, the interface 406 can include software supporting one or more communication protocols associated with communications. As such, the network 424 or the hardware of the interface can be operable to communicate physical signals within and outside of the illustrated computer 402.

The computer 402 includes a processor 408. Although illustrated as a single processor 408 in FIG. 4, two or more processors 408 can be used according to particular implementations of the computer 402 and the described functionality. Generally, the processor 408 can execute instructions and can manipulate data to perform the operations of the computer 402, including operations using algorithms, methods, functions, processes, flows, and procedures as described in the present disclosure.

The computer 402 also includes a database 420 that can hold data (for example, simulator data 422) for the computer 402 and other components connected to the network 424 (whether illustrated or not). For example, database 420 can be an in-memory, conventional, or a database storing data consistent with the present disclosure. In some implementations, database 420 can be a combination of two or more different database types (for example, hybrid in-memory and conventional databases) according to particular implementations of the computer 402 and the described functionality. Although illustrated as a single database 420 in FIG. 4, two or more databases (of the same, different, or combination of types) can be used according to particular implementations of the computer 402 and the described functionality. While database 420 is illustrated as an internal component of the computer 402, in alternative implementations, database 420 can be external to the computer 402.

The computer 402 also includes a memory 410 that can hold data for the computer 402 or a combination of components connected to the network 424 (whether illustrated or not). Memory 410 can store any data consistent with the present disclosure. In some implementations, memory 410 can be a combination of two or more distinct types of memory (for example, a combination of semiconductor and magnetic storage) according to implementations of the computer 402 and the described functionality. Although illustrated as a single memory 410 in FIG. 4, two or more memories 410 (of the same, different, or combination of types) can be used according to implementations of the computer 402 and the described functionality. While memory 410 is illustrated as an internal component of the computer 402, in alternative implementations, memory 410 can be external to the computer 402.

The application 412 can be an algorithmic software engine providing functionality according to implementations of the computer 402 and the described functionality. For example, application 412 can serve as one or more components, modules, or applications. Further, although illustrated as a single application 412, the application 412 can be implemented as multiple applications 412 on the computer 402. In addition, although illustrated as internal to the computer 402, in alternative implementations, the application 412 can be external to the computer 402.

The computer 402 can also include a power supply 418. The power supply 418 can include a rechargeable or non-rechargeable battery that can be configured to be either user- or non-user-replaceable. In some implementations, the power supply 418 can include power-conversion and management circuits, including recharging, standby, and power management functionalities. In some implementations, the power-supply 418 can include a power plug to allow the computer 402 to be plugged into a wall socket or a power source to, for example, power the computer 402 or recharge a rechargeable battery.

There can be any number of computers 402 associated with, or external to, a computer system containing computer 402, with each computer 402 communicating over network 424. Further, the terms “client,” “user,” and other appropriate terminology can be used interchangeably, as appropriate, without departing from the scope of the present disclosure. Moreover, the present disclosure contemplates that many users can use one computer 402 and one user can use multiple computers 402.

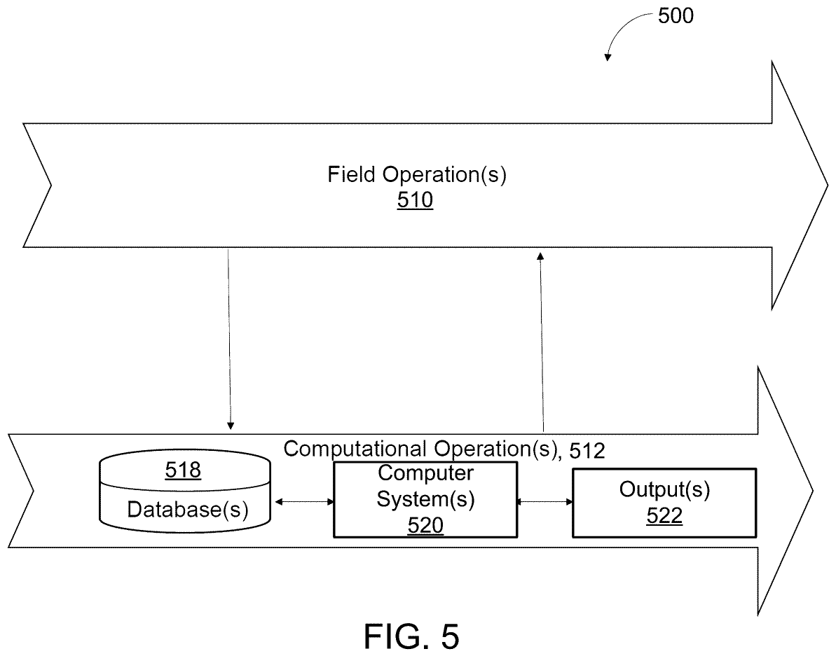

FIG. 5 illustrates hydrocarbon production operations 500 that include both one or more field operations 510 and one or more computational operations 512, which exchange information and control exploration for the production of hydrocarbons. In some implementations, outputs of techniques of the present disclosure can be performed before, during, or in combination with the hydrocarbon production operations 500, specifically, for example, either as field operations 510 or computational operations 512, or both.

Examples of field operations 510 include forming/drilling a wellbore, hydraulic fracturing, producing through the wellbore, injecting fluids (such as water) through the wellbore, to name a few. In some implementations, methods of the present disclosure can trigger or control the field operations 510. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 510 and responsively triggering the field operations 510 including, for example, generating plans and signals that provide feedback to and control physical components of the field operations 510. Alternatively or in addition, the field operations 510 can trigger the methods of the present disclosure. For example, implementing physical components (including, for example, hardware, such as sensors) deployed in the field operations 510 can generate plans and signals that can be provided as input or feedback (or both) to the methods of the present disclosure.

Examples of computational operations 512 include one or more computer systems 520 that include one or more processors and computer-readable media (e.g., non-transitory computer-readable media) operatively coupled to the one or more processors to execute computer operations to perform the methods of the present disclosure. The computational operations 512 can be implemented using one or more databases 518, which store data received from the field operations 510 and/or generated internally within the computational operations 512 (e.g., by implementing the methods of the present disclosure) or both. For example, the one or more computer systems 520 process inputs from the field operations 510 to assess conditions in the physical world, the outputs of which are stored in the databases 518. For example, seismic sensors of the field operations 510 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 512 where they are stored in the databases 518 and analyzed by the one or more computer systems 520.

In some implementations, one or more outputs 522 generated by the one or more computer systems 520 can be provided as feedback/input to the field operations 510 (either as direct input or stored in the databases 518). The field operations 510 can use the feedback/input to control physical components used to perform the field operations 510 in the real world.

For example, the computational operations 512 can process the seismic data to generate three-dimensional (3D) maps of the subsurface formation. The computational operations 512 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 512 to process information about the formation and control the drilling to adjust to the observed conditions in real-time.

The one or more computer systems 520 can update the 3D maps of the subsurface formation as information from one exploration well is received and the computational operations 512 can adjust the location of the next exploration well based on the updated 3D maps. Similarly, the data received from production operations can be used by the computational operations 512 to control components of the production operations. For example, production well and pipeline data can be analyzed to predict slugging in pipelines leading to a refinery and the computational operations 512 can control machine operated valves upstream of the refinery to reduce the likelihood of plant disruptions that run the risk of taking the plant offline.

In some implementations of the computational operations 512, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, based on processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart or are located in different countries or other jurisdictions.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random-access memory (RAM), read only memory (ROM), phase change memory (PRAM), static random-access memory (SRAM), dynamic random-access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Any claimed implementation is applicable to at least a computer-implemented method; a non-transitory, computer-readable medium storing computer-readable instructions to perform the computer-implemented method; and a computer system comprising a computer memory interoperable coupled with a hardware processor configured to perform the computer-implemented method or the instructions stored on the non-transitory, computer-readable medium.

While this specification contains many specific implementation details, these should not be construed as limitations on the scope of what may be claimed, but rather as descriptions of features that may be specific to implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

What is claimed is:

1. A method for executing a production simulation, the method comprising:
receiving, through a client device, an instruction for executing a portion of a production simulation;
responsive to receiving the instruction, accessing one or more digital agents, the one or more digital agents configured and trained with training data representing actions for operating one or more production simulations, the training data associating one or more simulation assets with respective data signatures each representing a scenario for executing a given simulation asset within the production simulation, wherein at least one of the one or more simulation assets includes the portion of the production simulation;
accessing, by the one or more digital agents, the simulation asset including the portion of the production simulation of the instruction;
executing the portion of the production simulation to generate output data; and
providing the output data to the client device.

2. The method of claim 1, wherein the one or more digital agents are available to the client device as a service.

3. The method of claim 1, wherein the one or more simulation assets include a digital twin representing a piece of physical hardware in the production.

4. The method of claim 1, wherein the one or more simulation assets include a sub-simulation asset, the sub-simulation asset configured to generate a specific data output that is specified in the instruction.

5. The method of claim 1, wherein the instruction is received through an interface comprising a chat bot or a digital input interface.

6. The method of claim 1, wherein the instruction is received responsive to providing the client device with one or more options for executing their production simulation.

7. The method of claim 1, further comprising:
providing, to the client device, one or more suggestions for one or more prerequisite portions of the production simulation that is required prior to executing the portion of the production simulation identified in the instruction.

8. A system configured for executing a production simulation, the system comprising:
one or more processors; and
a memory storing instructions that, when executed by the one or more processors, cause the one or more processors to perform operations comprising:
receiving, through a client device, an instruction for executing a portion of a production simulation;
responsive to receiving the instruction, accessing one or more digital agents, the one or more digital agents configured and trained with training data representing actions for operating one or more production simulations, the training data associating one or more simulation assets with respective data signatures each representing a scenario for executing a given simulation asset within the production simulation, wherein at least one of the one or more simulation assets includes the portion of the production simulation;
accessing, by the one or more digital agents, the simulation asset including the portion of the production simulation of the instruction;
executing the portion of the production simulation to generate output data; and
providing the output data to the client device.

9. The system of claim 8, wherein the one or more digital agents are available to the client device as a service.

10. The system of claim 8, wherein the one or more simulation assets include a digital twin Representing a piece of physical hardware in the production.

11. The system of claim 8, wherein the one or more simulation assets include a sub-simulation asset, the sub-simulation asset configured to generate a specific data output that is specified in the instruction.

12. The system of claim 8, wherein the instruction is received through an interface comprising a chat bot or a digital input interface.

13. The system of claim 8, wherein the instruction is received responsive to providing the client device with one or more options for executing their production simulation.

14. The system of claim 8, further comprising:
providing, to the client device, one or more suggestions for one or more prerequisite portions of the production simulation that is required prior to executing the portion of the production simulation identified in the instruction.

15. One or more non-transitory computer readable media storing instructions for executing a production simulation, the instructions, when executed by one or more processors, configured for causing the one or more processors to perform operations comprising:
receiving, through a client device, an instruction for executing a portion of a production simulation;
responsive to receiving the instruction, accessing one or more digital agents, the one or more digital agents configured and trained with training data representing actions for operating one or more production simulations, the training data associating one or more simulation assets with respective data signatures each representing a scenario for executing a given simulation asset within the production simulation, wherein at least one of the one or more simulation assets includes the portion of the production simulation;
accessing, by the one or more digital agents, the simulation asset including the portion of the production simulation of the instruction;
executing the portion of the production simulation to generate output data; and
providing the output data to the client device.

16. The one or more non-transitory computer readable media of claim 15, wherein the one or more digital agents are available to the client device as a service.

17. The one or more non-transitory computer readable media of claim 15, wherein the one or more simulation assets include a digital twin Representing a piece of physical hardware in the production.

18. The one or more non-transitory computer readable media of claim 15, wherein the one or more simulation assets include a sub-simulation asset, the sub-simulation asset configured to generate a specific data output that is specified in the instruction.

19. The one or more non-transitory computer readable media of claim 15, wherein the instruction is received responsive to providing the client device with one or more options for executing their production simulation.

20. The one or more non-transitory computer readable media of claim 15, further comprising:
providing, to the client device, one or more suggestions for one or more prerequisite portions of the production simulation that is required prior to executing the portion of the production simulation identified in the instruction.
